(19) United States
(12) Patent Application Publication
(10) Pub. No.: US 2022/0020862 A1
(43) Pub. Date: Jan. 20, 2022

(54) CARBON-FREE LAMINATED HAFNIUM OXIDE/ZIRCONIUM OXIDE FILMS FOR FERROELECTRIC MEMORIES

(71) Applicant: ENTEGRIS, INC., Billerica, MA (US)

(72) Inventors: Jun-Fei ZHENG, Westport, CT (US); Thomas H. BAUM, New Fairfield, CT (US)

(21) Appl. No.: 17/375,755

(22) Filed: Jul. 14, 2021

Related U.S. Application Data
(60) Provisional application No. 63/052,722, filed on Jul. 16, 2020.

(51) Int. Cl. H01L 29/51; H01L 21/02; C23C 16/455; C23C 16/40

(52) U.S. Cl. CPC H01L 29/511; H01L 29/516; C23C 16/405; H01L 21/02189; C23C 16/45553; H01L 21/02181

(57) ABSTRACT

Provided are carbon-free (i.e., less than about 0.1 atomic percentage of carbon) Zr doped HfO₂ films, where Zr can be up to the same level of Hf in terms of atomic percentage (i.e., 1% to 60%). The Zr doping can be achieved also by nanometer m laminated ZrO₂ and HfO₂ films useful in ferroelectric memories (FeRAM). The laminated films are comprised of about 5 to 10 layers of HfO₂ and ZrO₂ (i.e., alternating) films, each of which for example can be a thickness of about 1 to about 2 nm, wherein the laminated films are a total of about 5 to 10 nm in thickness.

### FIELD OF THE INVENTION

The invention belongs to the field of microelectronics. In particular, it relates to improvements in ferroelectric memory materials and structures comprising hafnium dioxide, zirconium dioxide films, mixed compositions of hafnium dioxide and zirconium dioxide, and electrodes.

### BACKGROUND OF THE INVENTION

Certain electronic devices have the ability to store and retrieve information in a memory structure or cell. Such memory cells are configured to store information bitwise. For example, the memory cell may have at least two states representing a logic 1 and a logic 0. The information thus stored may be read by determining the state of the memory cell. Such cells may be integrated on a wafer or a chip together with one or more logic circuits.

One type of volatile memory is a DRAM structure which allows for high speed and high capacity data storage. Examples of non-volatile memory structures include ROM, Flash structures, ferroelectric structures (for example, FeRAM and FeFET devices), and MRAM structures.

In the case of ferroelectric structures, they can be adapted in the form of a capacitor (e.g., FeRAM) or a transistor (FeFET), where information can be stored as a certain polarization state of the ferroelectric material within the structure. One example of ferroelectric materials and structures utilizes transition metal oxides such as hafnium dioxide mixed with zirconium dioxide.

Dielectric films comprised of hafnium oxide and zirconium oxide are generally prepared using atomic layer deposition and/or chemical vapor deposition techniques using organometallic hafnium and zirconium dialkylamide precursors. See, for example, “Atomic Layer Deposition of Hafnium and Zirconium Oxides using Metal Amide Precursors”, Dennis M. Hausmann, et al., Chem. Mater. 2002, 14, 4350-4358. Unfortunately, such methodology leads to dielectric films with low levels of carbon contamination which leads to leakage and charge-trap defects in the hafnium oxide/zirconium oxide dielectric films. These films may also evolve carbon during subsequent process steps within the device fabrication, thereby altering the film's properties. Thus, there is a need for methodology to fabricate such dielectric films which do not possess these levels of carbon and hence their concomitant shortcomings.

### SUMMARY OF THE INVENTION

In summary, the invention provides carbon-free (i.e., less than about 0.1 atomic percentage of carbon) Zr doped HfO₂ films, where Zr can be up to the same level of Hf in terms of atomic percentage (i.e., about 1% to about 60% via co-introduction of the precursors, or about 45% to about 55% or about 50%). The Zr doping can also be effectively achieved by nanometer laminated ZrO₂ and HfO₂ films (1% to 60% of Zr as compared to Hf) useful in ferroelectric memories (FeRAM). The laminated films are comprised of about 5 to 10 layers of HfO₂ and ZrO₂ (i.e., alternating) films, each of which for example can be a thickness of about 1 to about 2 nm, wherein the laminated films are a total of about 5 to 20 nm in thickness. The laminated films of the invention are expected to exhibit excellent ferroelectric and electrical properties for use in MIM (Metal-Insulator-Metal) and MIS ((Metal-Insulator-Silicon (or other channel)) structure based Ferroelectric memory applications. Such non-volatile memories generally provide high density, low power, rapid switching, low cost, and high endurance.

The laminated films of the invention can be prepared using ALD-type thermal deposition techniques utilizing HfCl₄ (or HfBr₄ or HfI₄) and ZrCl₄ (or ZrBr₄ or ZrI₄) and an oxidizing gas such as ozone, oxygen, water, N₂O or plasma O₂ as co-reactant, to deposit high quality, carbon-free films of HfO₂ and ZrO₂, respectively.

The invention also provides methodology for using HfCl₄, HfBr₄, HfI₄, ZrCl₄, ZrBr₄, and ZrI₄, to deposit hafnium oxide and zirconium oxide films having less than about 0.1 atomic percentage of carbon. Additionally, such films may also contain less than about 0.1 atomic percentage of the corresponding halogen, e.g., chlorine, bromine or iodine.

In a Metal-Insulator-Metal (M-I-M) memory device embodiment, the laminate hafnium oxide/zirconium oxide films of the invention have a top and bottom layers as electrodes comprised of at least one of titanium nitride, ruthenium, molybdenum, iridium, cobalt, tungsten, platinum, or conducting oxides of iridium and ruthenium. The top and bottom layers as electrodes may or not be the same material. In a Metal-Insulator-Semiconductor (M-I-S) memory device embodiment, the laminate hafnium oxide/zircomium oxide films may deposit directly on semiconductors and top layer as electrode comprised of at least one of titanium nitride, ruthenium, molybdenum, iridium, cobalt, tungsten, platinum, or conducting oxides of iridium and ruthenium

In a further embodiment, the laminate hafnium oxide/zirconium oxide films of the invention further comprise at least one outer surface comprised of iridium or iridium oxide. In a further embodiment, the laminate hafnium oxide/zirconium oxide films of the invention further comprise at least one outer surface comprised of titanium nitride.

### BRIEF DESCRIPTION OF THE DRAWINGS

FIG. 1 is a cross-sectional depiction of the laminate structure of the invention adapted to form an M-I-M structure for memory applications (FeRAM).

FIG. 2 is a cross-sectional depiction a laminate structure of the invention adapted to form a M-I-S structure for FeFET applications.

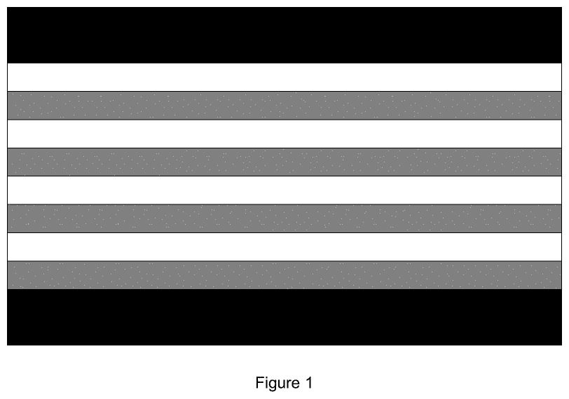

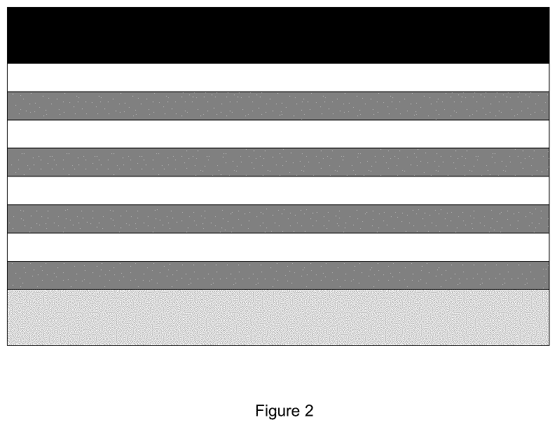

In the laminate films of the invention, as depicted in FIG. 1 and FIG. 2, the first or “starting” film can be either hafnium oxide or the zirconium oxide; similarly, the final or “finishing” film can be either hafnium oxide or zirconium oxide. In FIGS. 1 and 2, hafnium oxide is depicted as the starting film and zirconium oxide is depicted as the finishing film.

In FIGS. 1 and 2, the dark black layers indicate a metal layer, the white layers indicate a layer of hafnium oxide, the gray layer (in FIG. 1) represents a zirconium oxide layer, and a light gray (FIG. 2) layer indicates a Silicon layer or a layer comprising other channel materials.

### DETAILED DESCRIPTION OF THE INVENTION

In one aspect, the invention provides a hafnium oxide film having doped therein about 1 to about 60 atomic percentage of zirconium oxide, based on the total atomic percentage of the film, wherein the film contains less than about 0.1 atomic percentage of carbon, and less than about 0.1 atomic percentage of halogen. In other embodiments, the film has doped therein about 45 to 55, or about 50 atomic percentage of zirconium oxide.

In a second aspect, the invention provides a laminate film comprising alternating films of hafnium oxide and zirconium oxide, wherein said laminate film has a thickness of about 5 to about 10 nm in thickness, and wherein said laminate film has less than about 0.1 atomic percentage of carbon.

In one embodiment, the top and bottom films are hafnium oxide. In another embodiment, the top and bottom films are zirconium oxide. In another embodiment, the laminate film further comprises at least one dopant element chosen from silicon, aluminum, yttrium, and lanthanum.

As noted above in FIG. 1, the laminate film (i.e., the ferroelectric stack) may further comprise a metal layer on each side. In certain embodiments, said metal layer is comprised of titanium nitride, ruthenium, molybdenum, iridium, cobalt, tungsten, platinum, or conducting oxides of iridium or ruthenium.

As noted above in FIG. 2, the laminate film may further comprise a metal layer or surface on one side and a silicon or silicon-containing film on another side (e.g., Si₁₋ₓGeₓ, where x is greater than zero but less than one and represents varying proportions of each element in the alloy, referred to herein as “SiGe” for simplicity).

In a further embodiment, the laminate hafnium oxide/zirconium oxide films of the invention further comprise at least one outer surface comprised of iridium or iridium oxide.

In a further embodiment, the laminate hafnium oxide/zirconium oxide films of the invention further comprise at least one outer surface comprised of at least one of titanium nitride, ruthenium, molybdenum, iridium, cobalt, tungsten, platinum, or conducting oxides of iridium and ruthenium. In one embodiment, the at least one outer surface is titanium nitride.

In one embodiment, the laminate hafnium oxide/zirconium oxide films of the invention have a top layer (i.e., film) comprised of at least one of iridium and iridium oxide and/or a bottom layer (i.e., film) of at least one of titanium nitride, iridium, or iridium oxide, in both cases, as electrodes in the memory stack assembly.

The hafnium oxide and zirconium oxide films having less than about 0.1 atomic percentage of carbon may be deposited as films onto a substrate, for example a microelectronic device substrate, by utilizing a vapor deposition (i.e., thermal) process.

In certain embodiments, vapor deposition conditions comprise reaction conditions known as chemical vapor deposition, pulsed-chemical vapor deposition, and atomic layer deposition. In the case of pulsed-chemical vapor deposition, a series of alternating pulses of precursor compounds and co-reactant(s), either with or without an intermediate (inert gas) purge step, can be utilized to build up the film thickness to a desired endpoint.

In certain embodiments, the pulse time (i.e., duration of precursor exposure to the substrate) for the precursor compounds depicted above ranges between about 0.1 and 10 seconds. When a purge step is utilized, the duration is from about 1 to 4 seconds or 1 to 2 seconds. In other embodiments, the pulse time for the co-reactant ranges from 1 to 60 seconds. In other embodiments, the pulse time for the co-reactant ranges from about 1 to about 10 seconds.

In one embodiment, the vapor deposition conditions comprise a temperature of about 250° C. to about 750° C., and a pressure of about 1 to about 1000 Torr. In another embodiment, the vapor deposition conditions comprise a temperature of about 250° to about 650° C.

The hafnium tetrachloride (or iodide) and zirconium tetrachloride (or iodide) can be employed for forming high-purity hafnium dioxide and zirconium dioxide-containing films by any suitable vapor deposition technique, such as CVD, digital (pulsed) CVD, ALD, and pulsed plasma processes. Such vapor deposition processes can be utilized to form such films on microelectronic devices by utilizing deposition temperatures of from about 250° to about 550° C. to form films having a thickness of from about 20 angstroms to about 2000 angstroms.

In the process of the invention, the compounds above may be reacted with the desired microelectronic device substrate in any suitable manner, for example, in a single wafer CVD, ALD and/or PECVD or PEALD chamber, or in a furnace containing multiple wafers.

Alternately, the process of the invention can be conducted as an ALD or ALD-like process. As used herein, the terms “ALD or ALD-like” refers to processes such as (i) each reactant including the hafnium or zirconium precursor compound (I) and an oxidizing gas is introduced sequentially into a reactor such as a single wafer ALD reactor, semi-batch ALD reactor, or batch furnace ALD reactor, or (ii) each reactant, including the precursor compound and an oxidizing gas is exposed to the substrate or microelectronic device surface by moving or rotating the substrate to different sections of the reactor and each section is separated by an inert gas curtain, i.e., spatial ALD reactor or roll to roll ALD reactor.

As noted above, the vapor deposition processes further comprise a step involving exposing the substrate to an oxidizing gas such as O₂, O₃, N₂O, water vapor, alcohols or oxygen plasma. In certain embodiments, the oxidizing gas further comprises an inert carrier gas such as argon, helium, nitrogen, or a combination thereof.

The deposition methods disclosed herein may involve one or more purge gases. The purge gas, which is used to purge away unconsumed reactants and/or reaction by-products, is an inert gas that does not react with the precursors. Exemplary purge gases include, but are not limited to, argon, nitrogen, helium, neon, hydrogen, and mixtures thereof. In certain embodiments, a purge gas such as nitrogen or argon is supplied into the reactor at a flow rate ranging from about 10 to about 2000 sccm for about 0.1 to 1000 seconds, thereby purging the unreacted material and any byproduct that may remain in the reactor.

Energy is applied to the at least one of the precursor compounds and oxidizing gas to induce reaction and to form the hafnium dioxide or zirconium dioxide film on the microelectronic device substrate. Such energy can be provided by, but not limited to, thermal, pulsed thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively, a remote plasma-generated process in which plasma is generated ‘remotely’ of the reaction zone and substrate, being supplied into the reactor.

In one embodiment, the films are deposited using atomic layer deposition techniques, for example utilizing the ASM Pulsar® XP ALD reactor. By way of example, the deposition process can be done under the following conditions:

HfCl₄ (or ZrCl₄) ampoule temperature=170° C.

H₂O ampoule temperature=18-20° C.

Pressure=2-3 Torr

Flow rate=400-600 sccm (100-200 through HfCl₄ (or ZrCl₄)) ampoule

Substrate (i.e., chamber) temperature (T_{substrate})=300° C.

HfCl₄ (or ZrCl₄) pulse=0.5 to 1 second

H₂O pulse=0.1 to 0.2 second

In another example of the atomic layer deposition method, the HfCl₄ (or ZrCl₄) can be deposited on a 300 mm bare silicon wafer under the following conditions:

| | | | |
|---|---|---|---|
| Parameter | HfCl₄ | H₂O | Chamber |
| Temperature | 185° C. | 18° C. | 300° C. |
| Pressure | | | ~300 Torr |
| Flow (N₂) | 20-100 sccm | 50-100 sccm | 1300 sccm |
| Pulse Time | 0.1-1 second | 0.5 second | |
| Purge Time | 3 seconds | 3 seconds | |

As noted above, in other embodiments the films so formed utilizing this methodology also possess less than about 0.1 atomic percentage of halogens such as iodine, bromide and chlorine.

Thus, in a further aspect, the invention provides a method of using HfCl₄, HfBr₄, or HfI₄ to deposit hafnium oxide film on a substrate, said film having less than about 0.1 atomic percentage of carbon, which comprises alternately exposing a substrate to (i) HfCl₄, HfBr₄, or HfI₄ and (ii) an oxidizing gas, under vapor deposition conditions in a reaction zone. In one embodiment, the film possesses less than about 0.1 atomic percentage of halogen.

In a further aspect, the invention provides a method of using ZrCl₄, ZrBr₄, or ZrI₄, to deposit zirconium oxide film on a substrate, said film having less than about 0.1 atomic percentage of carbon, which comprises alternately exposing a substrate to (i) ZrCl₄, ZrBr₄, or ZrI₄ and (ii) an oxidizing gas, under vapor deposition conditions in a reaction zone. In another embodiment, the film possesses less than about 0.1 atomic percentage of halogen.

Insofar as hafnium tetrachloride (and tetraiodide) and zirconium tetrachloride (and iodide) are solids at room temperatures, a storage and delivery device such as the ProE-Vap® 100 delivery system, sold by Entegris, Inc., may be advantageously utilized. See also, U.S. Pat. Nos. 10,465,286; 10,392,700; 10,385,452; 9,469,89; and 9,004,462, incorporated herein by reference. Accordingly, an arrangement comprising dual solid delivery systems such as these can be utilized in a vapor deposition process to prepare the laminate films as described above, by alternately depositing hafnium dioxide and zirconium dioxide.

The invention has been described in detail with particular reference to certain embodiments thereof, but it will be understood that variations and modifications can be affected within the spirit and scope of the invention.

1. A hafnium oxide film having doped therein about 1 to about 60 atomic percentage of zirconium oxide, based on the total atomic percentage of the film, wherein the film contains less than about 0.1 atomic percentage of carbon, and less than about 0.1 atomic percentage of halogen.

2. The film of claim 1, wherein the film has doped therein about 45 to about 55 atomic percentage of zirconium oxide.

3. A laminate film comprising alternating films of hafnium oxide and zirconium oxide, wherein said laminate film has a thickness of about 5 to about 10 nm in thickness, and wherein said laminate film has less than about 0.1 atomic percentage of carbon.

4. The laminate film of claim 3, wherein the top and bottom films are hafnium oxide.

5. The laminate film of claim 3, wherein the top and bottom films are zirconium oxide.

6. The laminate film of claim 3, further comprising at least one dopant element chosen from silicon, aluminum, yttrium, and lanthanum.

7. The laminate film of claim 3, wherein said laminate film further comprises a metal layer on each side.

8. The laminate film of claim 7, wherein said metal layer is comprised of at least one of titanium nitride, ruthenium, molybdenum, iridium, cobalt, tungsten, platinum, or conducting oxides of iridium and ruthenium.

9. The laminate film of claim 3, wherein said laminate film further comprises a metal surface on one side and a silicon-containing film on another side.

10. The laminate film of claim 3, further comprising at least one outer surface comprised of iridium or iridium oxide.

11. The laminate film of claim 3, wherein said laminate film further comprises at least one outer surface comprised of titanium nitride.

12. The laminate film of claim 3, wherein the laminate film has a top layer comprised of at least one of iridium and iridium oxide and a bottom layer of titanium nitride.

13. The laminate film of claim 3, wherein the laminate film further comprises a metal layer or surface on one side and a silicon or silicon-containing film on another side.

14. The laminate film of claim 13, wherein the silicon-containing film is SiGe.

15. A method of using HfCl₄, HfBr₄, or HfI₄ to deposit hafnium oxide film on a substrate, said film having less than about 0.1 atomic percentage of carbon, which comprises alternately exposing a substrate to (i) HfCl₄, HfBr₄, or HfI₄ and (ii) an oxidizing gas, under vapor deposition conditions in a reaction zone.

16. The method of claim 15, wherein the film possesses less than about 0.1 atomic percentage of halogen.

17. A method of using ZrCl₄, ZrBr₄, or ZrI₄ to deposit zirconium oxide film on a substrate, said film having less than about 0.1 atomic percentage of carbon, which comprises alternately exposing a substrate to (i) ZrCl₄, ZrBr₄, or ZrI₄ and (ii) an oxidizing gas, under vapor deposition conditions in a reaction zone.

18. The method of claim 17, wherein the film possesses less than about 0.1 atomic percentage of halogen.
